(19) United States
(12) Patent Application Publication
(10) Pub. No.: US 2017/0059930 A1
(43) Pub. Date: Mar. 2, 2017

(54) DISPLAY SUBSTRATE, DISPLAY DEVICE AND MANUFACTURING METHOD THEREOF

(71) Applicant: Boe Technology Group Co., Ltd., Beijing (CN)

(72) Inventor: Yanbing Wu, Beijing (CN)

(21) Appl. No.: 15/135,693

(22) Filed: Apr. 22, 2016

(30) Foreign Application Priority Data
Aug. 28, 2015 (CN) 201510538310.3

(51) Int. Cl. G02F 1/1335; H01L 27/32; G02F 1/1362; G02F 1/1368; G02B 5/26; H01L 51/52; H01L 51/56

(52) U.S. Cl. CPC G02F 1/133514; H01L 51/5284; H01L 27/3262; H01L 27/3272; H01L 27/322; H01L 27/3258; H01L 51/56; H01L 51/5275; G02F 1/1368; G02B 5/26; G02F 1/136227; G02F 1/133512; H01L 2227/323; H01L 2251/558; H01L 2251/303; G02F 2001/133357

(57) ABSTRACT

This disclosure provides a display substrate, a display device and a manufacturing method thereof, and belongs to the field of display technologies. The display substrate comprises a base plate, and a blue light inhibition layer arranged on the base plate, wherein the blue light inhibition layer weakens a portion of blue light emitted by a light source. In this disclosure, by forming a blue light inhibition layer in the existing process for manufacturing a display device, it is unnecessary to significantly modify the manufacturing process, and thus the problem of blue light harm in a display device is solved in a simple and cost effective manner.

### RELATED APPLICATIONS

The present application claims the benefit of Chinese Patent Application No. 201510538310.3, filed Aug. 28, 2015, the entire disclosure of which is incorporated herein by reference.

### FIELD OF THE INVENTION

This disclosure relates to the field of display technologies, and specifically to a display substrate, a display device and a manufacturing method thereof.

### BACKGROUND ART

The white light generated by an LED (light emitting diode) is mainly achieved by a blue light chip in combination with yellow phosphor powder. The blue light refers to a visible light having a wavelength of about 400-500 nm. The wavelengths and intensities of blue light in the white light generated by LEDs are focused in the vicinity of 460 nm, e.g., 440-470 nm, which imposes a significant burden on eyes. When exposed to blue light for a long time, human eyes may suffer various injuries. The Commission Internationale d'Eclairage (CIE) promulgated in the year of 2002 CIE S009: 2002<PHOTOBIOLOGICAL SAFETY OF LAMPS AND LAMP SYSTEMS> where related harm of blue light was addressed for the first time. The International Electrotechnical Commission (IEC) published in the year of 2012 IEC/TR 62778 and specified three levels of radiation intensity harm of LED blue light. Many famous ophthalmologists in Japan have established a blue light research society with respect to the massive applications of LED backlights in advanced display devices to study the influence of blue light on the physical health such as eye retina, cornea, eye fatigue, sleep quality, neural system, obesity, cancer and so on. As can be seen, people have paid increasing attention to the blue light harm of LEDs.

A display device such as an LCD (liquid crystal display) usually adopts LEDs as the light source of the backlight module. Thus in some anti-blue light liquid crystal display devices, separate optical films are attached to the liquid crystal display devices for filtering a portion of high energy blue light in the wavelength band of 440-470 nm emitted by the LEDs. In this case, an additional optical film is required, which leads to an increase in cost and thickness. In other anti-blue light liquid crystal display devices, the backlight is adapted such that the blue light emitted therefrom or the peak of the blue light emitted therefrom falls within a particular wavelength band. In this case, it is necessary to adjust the light source, so the cost will be high and the power consumption will increase. Similarly, the problem of blue light harm also exists in an OLED (organic light emitting display).

Therefore, there is a need for an improved method and display device for preventing blue light harm in the art.

### SUMMARY

The object of this disclosure is to alleviate or solve one or more of the problems mentioned above. Specifically, the display substrate, the display device and the manufacturing method thereof in this disclosure is compatible with the manufacturing process of an existing display device, so it is unnecessary to modify the manufacturing process and apparatus hardware, and thus the problem of blue light harm in a display device is solved in a simple and cost effective manner.

In a first aspect, a display substrate is provided, the display substrate comprising: a base plate; and a blue light inhibition layer arranged on the base plate, wherein the blue light inhibition layer weakens a portion of blue light emitted by a light source.

According to this technical solution, the blue light inhibition layer is formed during manufacturing an existing display substrate. That is, the manufacturing process of the blue light inhibition layer is compatible with the existing process for manufacturing a display device, so it is unnecessary to significantly modify the manufacturing process, and thus the problem of blue light harm in a display device is solved in a simple and cost effective manner. Besides, the blue light inhibition layer is formed in the display substrate, which helps to reduce the thickness of the display substrate and thereby reduce the thickness of the display device.

For example, the blue light inhibition layer is directly formed on the base plate.

According to this technical solution, the blue light inhibition layer is directly formed on the base plate of the display substrate. Thereby, the blue light inhibition layer is formed on the base plate in advance, which facilitates modular operations and avoids occupying the up time of a manufacturing device, thus improving the operation ratio of the device.

For example, the display substrate further comprises a thin film transistor, a passivation layer and a pixel electrode formed on the base plate; and the thin film transistor comprises a gate, a gate insulation layer, an active region and a source/drain electrode.

According to this technical solution, the display substrate is an array substrate. In particular, the blue light inhibition layer according to this disclosure is formed in an array substrate of a display device. The array substrate usually comprises several dielectric layers, i.e., the manufacturing process of the array substrate by itself relates to steps of forming dielectric layers. This is quite favorable for the formation of the blue light inhibition layer according to this disclosure, particularly when the blue light inhibition layer is formed by one or more transparent dielectric layers.

For example, the blue light inhibition layer is formed on the gate insulation layer; and the pixel electrode is electrically connected to the source/drain electrode of the thin film transistor through a via hole penetrating through the passivation layer.

According to this technical solution, the blue light inhibition layer is formed after the gate insulation layer of the thin film transistor is formed. This facilitates compatibility with the existing process for manufacturing an array substrate. For example, the gate insulation layer and the blue light inhibition layer are formed sequentially in a same film forming chamber.

For example, the blue light inhibition layer is formed on the passivation layer; and the pixel electrode is electrically connected to the source/drain electrode of the thin film transistor through a via hole penetrating through the blue light inhibition layer and the passivation layer.

According to this technical solution, the blue light inhibition layer is formed after the passivation layer of the thin film transistor is formed. This facilitates compatibility with the existing process for manufacturing an array substrate. For example, the passivation layer and the blue light inhibition layer are formed sequentially in a same film forming chamber. In the specific embodiments, the display substrate further comprises a planarizing layer formed on the passivation layer. In this case, the blue light inhibition layer is formed on the planarizing layer. Generally speaking, the blue light inhibition layer can be disposed on any dielectric layer of the array substrate, which helps to integrate the forming step of a blue light inhibition layer with the existing process for manufacturing an array substrate.

For example, the display substrate comprises a blue subpixel region and a non-blue subpixel region, and in a display area of the non-blue subpixel region, the display substrate comprises the base plate and the pixel electrode formed on the base plate.

The blue light inhibition layer also reflects to a certain degree light of other colors emitted by the light source, for example, red light and green light. According to this technical solution, the blue light inhibition layer in the display area of the non-blue subpixel region is etched away so as to avoid the influence on lights other than blue light.

For example, in the display area of the non-blue subpixel region, the display substrate comprises the base plate, a planarizing layer and the pixel electrode formed on the planarizing layer.

According to this technical solution, when the blue light inhibition layer in the display area of the non-blue subpixel region is etched away, a planarizing layer is deposited, and then a pixel electrode is formed on the planarizing layer. The planarizing layer eliminates a significant difference in height caused by etching away the blue light inhibition layer in the display area of the non-blue subpixel region, and hence avoids possible short circuits between conductive layers on different layers due to the difference in height.

For example, the display substrate further comprises a black matrix layer and a color filter which are formed on the blue light inhibition layer.

According to this technical solution, the display substrate is a color filter substrate. In particular, the blue light inhibition layer according to this disclosure is arranged in a color filter substrate, and specifically on a base plate of the color filter substrate.

For example, the display substrate further comprises a thin film transistor and a pixel electrode which are formed on a first side of the base plate, and a black matrix layer and a color filter which are formed on the first side or a second side of the base plate; and the blue light inhibition layer is formed on the first or second side of the base plate.

According to this technical solution, the display substrate is a COA (color filter on array) substrate. Specifically, in the COA substrate, the thin film transistor and the color filter are formed on respective sides or a same side of the base plate respectively. The blue light inhibition layer according to this disclosure is formed either on the thin film transistor side of the COA substrate, or on the other side of the COA substrate.

For example, in the optical path of the blue light emitted by the light source, the blue light inhibition layer comprises a first transparent dielectric layer and a second transparent dielectric layer which are arranged on a transparent dielectric base layer; a refractive index n₁ of the first transparent dielectric layer is greater than a refractive index n₀ of the transparent dielectric base layer; and the refractive index n₁ of the first transparent dielectric layer is greater than a refractive index n₂ of the second transparent dielectric layer.

According to this technical solution, the blue light inhibition layer comprises a transparent dielectric base layer, a first transparent dielectric layer and a second transparent dielectric layer sequentially, and their refractive indexes satisfy n₀<n₁>n₂. Thereby, for light incident from the light source, these three layers together function as a reflection enhancement film and thus light incident from the light source is weakened. In particular, the transparent dielectric base layer is an existing dielectric layer in the array substrate, for example, a gate insulation layer, a passivation layer, a planarizing layer or a protection layer. Accordingly, the blue light inhibition layer in this disclosure is better compatible with the existing process for manufacturing an array substrate and helps to reduce the thickness of the display substrate.

For example, a thickness d of the first transparent dielectric layer is d=(2m+1)λ(4n₁), wherein m is a natural number, n₁ is the refractive index of the first transparent dielectric layer, and λ is the wavelength of the blue light to be weakened.

According to this technical solution, when the thickness of the first transparent dielectric layer in the blue light inhibition layer is greater than λ/4 by a factor of an odd number, the blue light inhibition layer reaches a maximum reflectivity

$${R}_{max} = {( \frac{{n}_{0} \cdot {n}_{2} - {n}_{1}^{2}}{{n}_{0} \cdot {n}_{2} + {n}_{1}^{2}} )}^{2}$$

with respect to incident blue light having a wavelength of λ, and weakens the blue light within the target wavelength band to a maximum extent, thereby solving the problem of blue light harm.

For example, the blue light inhibition layer comprises two or more groups of the first transparent dielectric layer and the second transparent dielectric layer stacked in sequence.

When the blue light inhibition layer comprises multiple groups of the first transparent dielectric layer and the second transparent dielectric layer, the transmissivity of the blue light inhibition layer with respect to the incident light is expressed as

$${T}_{2 k + 1} = 4 \frac{{n}_{G}}{{n}_{1}^{2}} {( \frac{{n}_{2}}{{n}_{1}} )}^{2 k} ,$$

wherein k is a number of the groups of the first transparent dielectric layer and the second transparent dielectric layer in the blue light inhibition layer, 2k+1 is a total number of the dielectric layers in the blue light inhibition layer, n₁ is the refractive index of the first transparent dielectric layer, n₂ is the refractive index of the second transparent dielectric layer, and n_{G} is the refractive index of a material arranged above the topmost second transparent dielectric layer of the blue light inhibition layer. As known from the above formula, in case the number of groups of the first and second transparent dielectric layers is increased by one, the transmissivity of the blue light inhibition layer is reduced by a factor of 1/(n₂/n₁)². That is, an increase in the group number of the first transparent dielectric layer and the second transparent dielectric layer decreases the transmissivity T with respect to the incident light, and thus help to increase the reflectivity R with respect to the incident light. It should be pointed out that when the transmissivity T is so small that the absorption and the dispersion in the blue light inhibition layer cannot be ignored, R=1−T is no longer true. At this point, although the transmissivity T continues decreasing, the reflectivity R will not increase any more, so the reflectivity of the blue light inhibition layer reaches its limit. In embodiments, the blue light inhibition layer comprises for instance 500 groups of the first transparent dielectric layer and the second transparent dielectric layer, i.e., the total number of the dielectric layers is 1001.

For example, the refractive indexes of the first transparent dielectric layer and the second transparent dielectric layer differ by at least 0.3.

According to this technical solution, the refractive indexes of the first transparent dielectric layer and the second transparent dielectric layer differ by at least 0.3. As can be seen from the above expressions such as

$${R}_{max} = {( \frac{{n}_{0} \cdot {n}_{2} - {n}_{1}^{2}}{{n}_{0} \cdot {n}_{2} + {n}_{1}^{2}} )}^{2}$$

and the factor 1/(n₂/n₁)², the greater difference (n₁−n₂) the first transparent dielectric layer and the second transparent dielectric layer have in the refractive indexes, the better reflection enhancement effect the blue light inhibition layer achieves.

For example, the transparent dielectric base layer is SiO₂, the first transparent dielectric layer is SiNₓ, and the second transparent dielectric layer is SiO₂.

According to this technical solution, the transparent dielectric base layer is SiO₂, the first transparent dielectric layer is SiNₓ, and the second transparent dielectric layer is SiO₂. These materials are conventional dielectric materials in the manufacturing process of a display substrate, and this facilitates the compatibility of the technical solution of this disclosure with the existing process for manufacturing the display substrate. Apparently, the technical solution of this disclosure is not limited by that. For example, the low refractive index material in the blue light inhibition layer is SiON, and the high refractive index material is TiO₂, ZrO₂, HfO₂, Ta₂O₅ or Nb₂O₅.

For example, the thickness of the first transparent dielectric layer is 58-62 nm.

As can be known from the above expression d=(2m+1)λ/(4n₁), when m=0, the relationship between the thickness d of the first transparent dielectric layer and the wavelength λ of the incident light to be weakened satisfies λ=d/(4n₁). According to this technical solution, the material of the first transparent dielectric layer is SiNₓ, i.e., n₁=1.9, and the thickness is 58-62 nm, and it is derived that the wavelength λ to be weakened is 440-470 nm. That is, according to this technical solution, blue light in the wavelength band of 440-470 nm emitted by the light source is effectively weakened, and thereby blue light harm is effective prevented.

In a second aspect, this disclosure provides a display device comprising the display substrate mentioned above.

In a third aspect, this disclosure provides a method for manufacturing a display device, wherein during manufacturing the display substrate of the display device, the method comprises the following step of: forming in the display substrate a blue light inhibition layer in the path of blue light emitted by a light source.

For example, the step of forming a blue light inhibition layer comprises: directly forming a blue light inhibition layer on a base plate of the display substrate.

For example, the step of forming a blue light inhibition layer comprises: forming a blue light inhibition layer on a dielectric layer in the display substrate.

For example, after the step of forming a blue light inhibition layer, the method comprises: etching away the blue light inhibition layer in a display area of a non-blue light subpixel region of the display substrate.

The display device according to this disclosure and the manufacturing method thereof have the same or similar benefits as the display substrate mentioned above, which will not be described herein for simplicity

According to this disclosure, by forming a blue light inhibition layer in the existing process for manufacturing a display device, it is unnecessary to significantly modify the manufacturing process, and thus the problem of blue light harm in a display device is solved in a simple and cost effective manner. Besides, the blue light inhibition layer is formed in the display substrate, which helps to reduce the thickness of the display substrate and thereby reduce the thickness of the display device.

### BRIEF DESCRIPTION OF DRAWINGS

FIG. 1 is a schematic structural view of a liquid crystal display device according to an embodiment of this disclosure;

FIG. 2 is a schematic sectional view of a display substrate according to an embodiment of this disclosure;

FIGS. 3a, 3b, 3c, 3d and 3e are schematic sectional views of a display substrate according to an embodiment of this disclosure in each manufacturing phase;

FIGS. 4a and 4b are schematic sectional views of a display substrate according to an embodiment of this disclosure; and

FIG. 5 is a schematic sectional view of a display substrate according to an embodiment of this disclosure.

### DETAILED DESCRIPTION OF EMBODIMENTS

The specific embodiments of the display substrate of this disclosure, the display device and the manufacturing method thereof shall be explained in details as follows with reference to the drawings. The drawings of this disclosure schematically illustrate structures, portions and/or steps related to the inventive concepts, but do not illustrate or only partially illustrate structures, portions and/or steps unrelated to the inventive concepts.

Reference signs: 1 liquid crystal display device; 10 backlight module; 20 array substrate; 30 color filter substrate; 40 liquid crystal layer; 100, 300 base plate; 102 gate insulation layer; 104, 302 blue light inhibition layer; 106 passivation layer; 108 planarizing layer; 110, 210 gate; 120, 220 active region; 130, 230 source/drain; 150, 250, 160, 260, 170, 270 pixel electrode; 151, 251, 161, 261, 171, 271 via hole; 101A, 301A blue subpixel region; 1018, 301B, 301C non-blue subpixel region; 304 black matrix layer; and 306 color filter.

As shown in FIG. 1, a liquid crystal display device 1 usually comprises a backlight module 10, an array substrate 20, a color filter substrate 30 and a liquid crystal layer 40 arranged between the array substrate 20 and the color filter substrate 30. The backlight module 20 comprises a light source, a light guide plate, an optical film and so on (no shown), and provides backlight for the display substrate, i.e., the array substrate 20 and the color filter substrate 30.

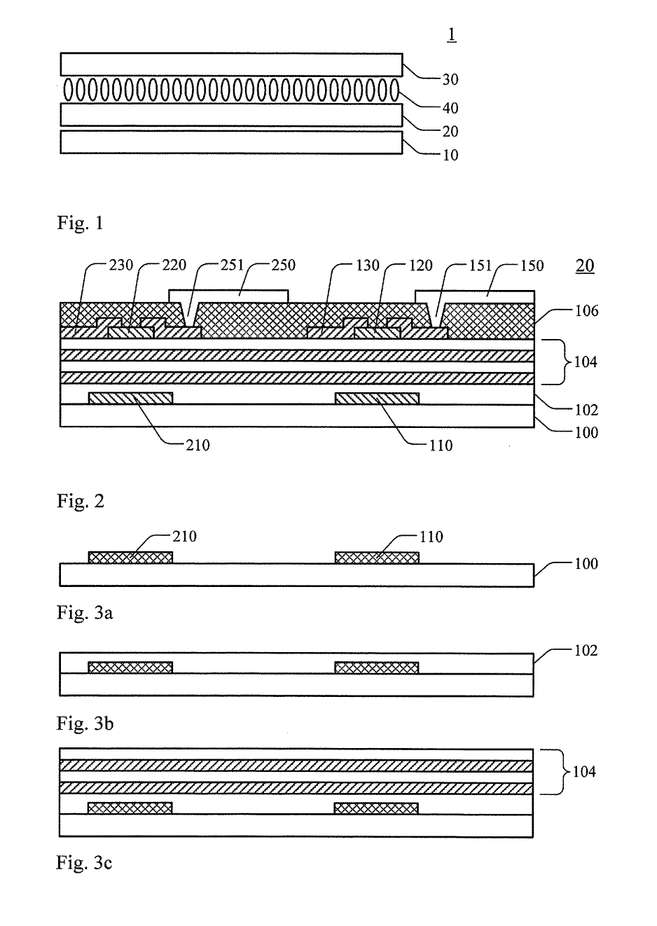

FIG. 2 schematically illustrates a display substrate according to an embodiment of this disclosure. As shown in FIG. 2, the display substrate 20 comprises a base plate 100, and gates 110, 210 stacked on the base plate 100 sequentially, a gate insulation layer 102, active regions 120, 220, source/drain electrode 130, 230, a passivation layer 106 and pixel electrodes 150, 250. As can be seen, the display substrate 20 in the embodiment is the array substrate 20 in the liquid crystal display device 1. For the sake of simplicity, FIG. 2 only schematically shows two subpixel regions in the display substrate 20. In each subpixel region, the pixel electrodes 150 and 250 are electrically connected to the source/drain electrode 130, 230 respectively through via holes 151, 251 that penetrate through the passivation layer 106. It should be pointed out that a planarizing layer (not shown) can be provided above the passivation layer 106. The pixel electrodes 150, 250 are then formed on the planarizing layer, and electrically connected to the source/drain electrode 130, 230 through via holes 151, 251 that penetrate through the planarizing layer and the passivation layer 106.

According to this disclosure, the display substrate 20 comprises a base plate 100 and a blue light inhibition layer 104 arranged on the base plate 100. The blue light inhibition layer 104 weakens a portion of blue light emitted by the backlight module 10.

For example, in the optical path of blue light emitted by the backlight module 10, the blue light inhibition layer 104 can comprise a first transparent dielectric layer and a second transparent dielectric layer which are arranged on a transparent dielectric base layer. The refractive index n₁ of the first transparent dielectric layer is greater than the refractive index n₀ of the transparent dielectric base layer; and the refractive index n₁ of the first transparent dielectric layer is greater than the refractive index n₂ of the second transparent dielectric layer. Since the refractive indexes of the transparent dielectric base layer, the first transparent dielectric layer and the second transparent dielectric layer satisfy n₀<n₁>n₂, for light incident from the backlight module, these three layers together function as a reflection enhancement film and hence light incident from the backlight module 10 is weakened. In particular, the transparent dielectric base layer can be an existing dielectric layer in the array substrate, for example, a gate insulation layer, a passivation layer, a planarizing layer or a protection layer. Accordingly, the blue light inhibition layer 104 can be better compatible with the existing process for manufacturing an array substrate and help to reduce the thickness of the display substrate.

The thickness d of the first transparent dielectric layer can be d=(2m+1)λ/(4n₁), wherein m is a natural number, n₁ is the refractive index of the first transparent dielectric layer, and λ is the wavelength of the blue light to be weakened. When the thickness of the first transparent dielectric layer in the blue light inhibition layer 104 is greater than λ/4 by a factor of an odd number, the blue light inhibition layer 104 reaches a maximum reflectivity

$${R}_{max} = {( \frac{{n}_{0} \cdot {n}_{2} - {n}_{1}^{2}}{{n}_{0} \cdot {n}_{2} + {n}_{1}^{2}} )}^{2}$$

with respect to incident blue light having a wavelength of λ, and weakens the blue light within the target wavelength band to a maximum extent, thereby solving the problem of blue light harm.

The blue light inhibition layer 104 can comprise two or more groups of the first transparent dielectric layer and the second transparent dielectric layer stacked in sequence. When the blue light inhibition layer 104 comprises multiple groups of the first transparent dielectric layer and the second transparent dielectric layer, the transmissivity of the blue light inhibition layer 104 with respect to the incident light can be expressed as

$${T}_{2 k + 1} = 4 \frac{{n}_{G}}{{n}_{1}^{2}} {( \frac{{n}_{2}}{{n}_{1}} )}^{2 k} ,$$

wherein k is the group number of the first transparent dielectric layer and the second transparent dielectric layer in the blue light inhibition layer 104, 2k+1 is the total number of the dielectric layers in the blue light inhibition layer 104, n₁ is the refractive index of the first transparent dielectric layer, n₂ is the refractive index of the second transparent dielectric layer, and n_{G} is the refractive index of a material arranged above the topmost second transparent dielectric layer of the blue light inhibition layer 104. As can be known from the above formula, in case the number of groups of the first and second transparent dielectric layers is increased by one, the transmissivity of the blue light inhibition layer 104 is reduced by a factor of 1/(n₂/n₁)². That is, an increase in the group number of the first transparent dielectric layer and the second transparent dielectric layer can decrease the transmissivity T with respect to the incident light, which helps to increase the reflectivity R with respect to the incident light. It should be pointed out that when the transmissivity T is so small that the absorption and the dispersion in the blue light inhibition layer 104 cannot be ignored, R=1−T is no longer true. At this point, although the transmissivity T can continue decreasing, the reflectivity R will not increase any more, so the reflectivity of the blue light inhibition layer reaches its limit. In the embodiments, the blue light inhibition layer can comprise for instance 500 groups of the first transparent dielectric layer and the second transparent dielectric layer, i.e., the total number of the dielectric layers is 1001.

The refractive indexes of the first transparent dielectric layer and the second transparent dielectric layer of the blue light inhibition layer 104 can differ by at least 0.3. As can be seen from the above expressions such as

$${R}_{max} = {( \frac{{n}_{0} \cdot {n}_{2} - {n}_{1}^{2}}{{n}_{0} \cdot {n}_{2} + {n}_{1}^{2}} )}^{2}$$

and the factor 1/(n₂/n₁)², the greater difference (n₁−n₂) the first transparent dielectric layer and the second transparent dielectric layer have in the refractive indexes, the better reflection enhancement effect the blue light inhibition layer 104 achieves.

For example, the transparent dielectric base layer can be SiO₂, the first transparent dielectric layer can be SiNₓ, and the second transparent dielectric layer can be SiO₂. These materials are conventional dielectric materials in the manufacturing process of the display substrate 20, and this helps the blue light inhibition layer 104 to be compatible with the existing process for manufacturing the display substrate 20. In addition, the low refractive index material in the blue light inhibition layer 104 can further be SiON, and the high refractive index material can further be TiO₂, ZrO₂, HfO₂, Ta₂O₅ or Nb₂O₅.

As can be known from the above expression d=(2m+1)λ/(4n₁), when m=0, the relationship between the thickness d of the first transparent dielectric layer and the wavelength λ of the incident light to be weakened satisfies λ=d/(4n₁). When the material of the first transparent dielectric layer is SiNₓ, i.e., n₁=1.9, and the thickness of the first transparent dielectric layer is 58-62 nm, the wavelength λ to be weakened by the blue light inhibition layer 104 is 440-470 nm. That is, the blue light inhibition layer 104 can effectively weaken blue light in the wavelength band of 440-470 nm emitted from the backlight module 10, and thereby effectively prevent blue light harm.

As shown in FIG. 2, the array substrate 20 comprises the blue light inhibition layer 104. Since the array substrate 20 usually comprises several dielectric layers, e.g., a gate insulation layer, a passivation layer, a planarizing layer and a protection layer. That is, the manufacturing process of the array substrate 20 by itself relates to steps of forming dielectric layers. This is quite favorable for the formation of the blue light inhibition layer 104, in particular when the blue light inhibition layer 104 is formed by one or more transparent dielectric layers.

As shown, the blue light inhibition layer 104 is arranged on the gate insulation layer 102 of the thin film transistor, so it is possible to form the blue light inhibition layer 104 after the formation of the gate insulation layer 102 of the thin film transistor. This helps the blue light inhibition layer 104 to be compatible with the existing process for manufacturing the array substrate 20.

As shown in FIG. 2, the blue light inhibition layer 104 is formed above the gate insulation layer 102. In this case, the gate insulation layer 102 can serve as the transparent dielectric base layer in the blue light inhibition layer 104. That is, the blue light inhibition layer 104 may comprise only a first transparent dielectric layer and a second transparent dielectric layer. The refractive index n₁ of the first transparent dielectric layer is greater than the refractive index n₀ of the gate insulation layer 102, and the refractive index n₁ of the first transparent dielectric layer is greater than the refractive index n₂ of the second transparent dielectric layer. Thereby, the blue light inhibition layer 104 formed by the gate insulation layer 102, the first transparent dielectric layer and the second transparent dielectric layer stacked in sequence forms a reflection enhancement film with respect to light incident from the backlight module 10 and hence effectively prevents blue light harm.

As shown in FIG. 2, the blue light inhibition layer 104 comprises two groups of the first transparent dielectric layer and the second transparent dielectric layer. As mentioned above, the blue light inhibition layer 104 can comprise more groups of the first transparent dielectric layer and the second transparent dielectric layer so as to further increase the reflectivity of the blue light inhibition layer 104 with respect to the incident light.

In the case as shown in FIG. 2, the blue light inhibition layer 104 is formed on the gate insulation layer 102. However, it can be also arranged on dielectric layers of the array substrate 20 such as the passivation layer, the planarizing layer and the protection layer with similar technical effects achieved when it is arranged on the gate insulation layer 102. For example, the blue light inhibition layer 104 can be formed on the passivation layer 106. In this case, the pixel electrodes 150, 250 can be electrically connected to the source/drain electrode 130, 230 through a via hole penetrating through the blue light inhibition layer 104 and the passivation layer 106.

Besides, the blue light inhibition layer 102 can also be directly formed on the base plate 100. In this case, the blue light inhibition layer 104 can be formed on the base plate 100 in advance. This facilitates modular operations and thus avoids occupying the up time for the manufacturing device, thereby improving the operation ratio of the device.

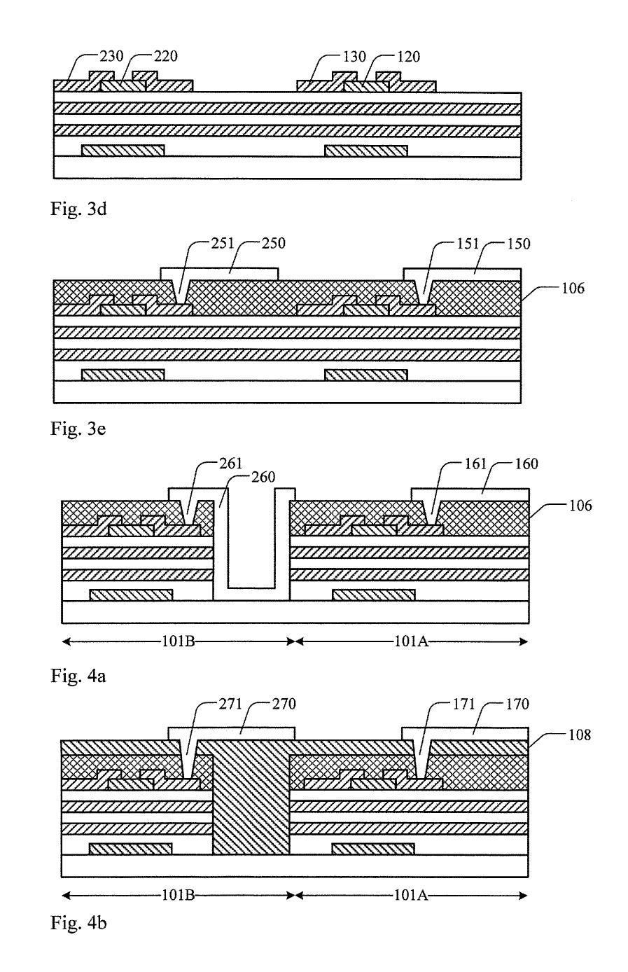

FIGS. 3a, 3b, 3c, 3d and 3e schematically illustrate an array substrate 20 in each manufacturing phase.

As shown in FIG. 3a, a metal layer is deposited on the base plate 100 such as glass, and patterns of the gates 110, 210 are formed by a patterning process. The metal layer can be Al, Cu, Mo, Ti, Cr, W or an alloy thereof. The gates 110, 210 can be either a monolayered structure or a multilayered structure, e.g., Mo\Al\Mo, Ti\Cu\Ti, Mo\Ti\Cu.

As shown in FIG. 3b, a transparent dielectric base layer is deposited on the gate 210 to form a gate insulation layer 102. The gate insulation layer 102 can be SiO₂ with a refractive index of 1.5, and can have a thickness of 50-1000 nm. The gate insulation layer 102 can insulate the gates 110, 210 from the overlying circuits and avoid the gates 110, 210 from being oxidized.

As shown in FIG. 3c, a first transparent dielectric layer and a second transparent dielectric layer are deposited sequentially on the gate insulation layer 102, thereby forming a blue light inhibition layer 104. For example, in order to eliminate the high energy blue light in the wavelength band of 440-470 nm to prevent blue light harm, the first transparent dielectric layer can be SiNₓ with a thickness of 58-62 nm. The refractive index of the first transparent dielectric layer is greater than that of the gate insulation layer 102, and the refractive index of the first transparent dielectric layer is greater than that of the second transparent dielectric layer. The second transparent dielectric layer can be SiO₂. The refractive indexes of the first and second transparent dielectric layers differ by at least 0.3. That is, the refractive index of the first transparent dielectric layer is greater than that of the second transparent dielectric layer by at least 0.3 such that the reflectivity of the blue light inhibition layer 104 is enhanced with respect to blue light. Alternatively, a first transparent dielectric layer and a second transparent dielectric layer are further deposited on the second transparent dielectric layer sequentially. The larger the number of the first and second transparent dielectric layers in the blue light inhibition layer 104 is, the more blue light it reflects, i.e., the better the blue light harm is prevented. With an increasing layer number, the manufacture cost will also rise. In the actual application, the total layer number of the first and second transparent dielectric layers can be 1000.

As shown in FIG. 3d, patterns of a semiconductor layer and a signal line are manufactured on the blue light inhibition layer 104 so as to form active regions 120, 220, source/drain electrodes 130, 230 and a data line (not shown).

As shown in FIG. 3e, a passivation layer 106 is formed on the structure of FIG. 3d and via holes 151, 251 are formed by a patterning process. Then a metal layer is deposited and pixel electrodes 150, 250 are formed by a patterning process. Thereby the manufacture of an array substrate is accomplished and the array substrate 20 as shown in FIG. 2 is obtained. It should be pointed out that in the actual application, a planarizing layer and/or a protection layer can be further arranged above the passivation layer 106.

FIGS. 4a and 4b schematically illustrate a display substrate according to an embodiment of this disclosure. As shown in FIG. 4a, the array substrate 20 is divided into a blue subpixel region 101A and a non-blue subpixel region 101B. The blue light inhibition layer 104 will not only reflect blue light in the blue subpixel region 101A, but also reflect to a certain degree lights of other colors, e.g., red light and green light in the non-blue subpixel region 101B. Therefore, when a patterning process is carried out on the passivation layer 106 so as to form via holes 151, 251 as shown in FIG. 3e, the blue light inhibition layer 104 in the display area of the non-blue subpixel region 101B can be etched away at the same time, thereby avoiding the influence on lights other than blue light. That is, in the display area of the non-blue subpixel region 101B, the array substrate 20 comprises the base plate 100 and the pixel electrode 260 formed on the base plate 100.

As shown in FIG. 4b, after the blue light inhibition layer 104 in the display area of the non-blue subpixel region 101B is etched away, a planarizing layer 108 can be deposited, and then pixel electrodes 170, 270 are formed on the planarizing layer 108. The pixel electrodes 170, 270 are electrically connected to the source/drain electrode 130, 230 respectively through via holes 171, 271 that penetrate through the planarizing layer 108 and the passivation layer 106. The planarizing layer 108 can eliminate a significant difference in height caused in the display area of the non-blue subpixel region 101B when the blue light inhibition layer is etched away, and hence avoid possible short circuits between conductive layers on different layers due to the difference in height. That is, in the display area of the non-blue subpixel region 101B, the array substrate 20 can comprise the base plate 100, the planarizing layer 108 and the pixel electrode 270 formed on the planarizing layer.

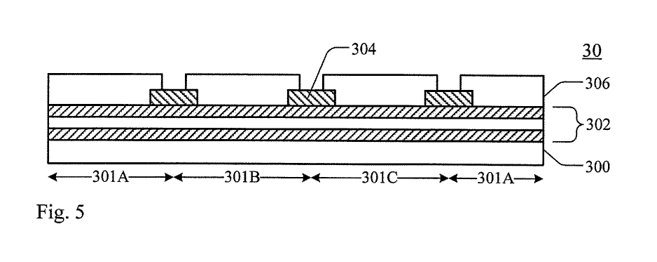

In the embodiments of FIGS. 2, 3a, 3b, 3c, 3d, 3e, 4a and 4b, the blue light inhibition layer 104 is shown as being arranged in the array substrate 20. However, the blue light inhibition layer in this disclosure can also be arranged in other display substrates. For example, FIG. 5 schematically illustrates a display substrate according to an embodiment of this disclosure. The display substrate 30 comprises a base plate 300, a blue light inhibition layer 302, a black matrix layer 304 and a color filter 306. That is, the display substrate 30 is a color base plate 30. As shown, the blue light inhibition layer 302 is arranged on the base plate 300 of the color filter substrate 30.

As shown in FIG. 5, the color filter substrate 30 is divided into a blue subpixel region 301A and non-blue subpixel regions 301B, 301C. As mentioned above, a blue light inhibition layer 302 can be formed over the entire base plate 300. Alternatively, in the display area of the non-blue subpixel regions 301B, 301C, the blue light inhibition layer 302 can be etched away so as to avoid influence on lights other than blue light. That is, reference can be made to the above disclosure about the array substrate 20 for details about the arrangement of the blue light inhibition layer 302 in the color filter substrate 30 and the manufacturing method thereof, which will not be described herein for simplicity.

Besides, the display substrate comprising a blue light inhibition layer in this disclosure can further be a color filter on array (COA) substrate. Specifically, in the COA substrate, the thin film transistor and the color filter are formed on respective sides of the base plate respectively. The blue light inhibition layer can be formed either on the thin film transistor side of the COA substrate, or on the color filter side of the COA substrate.

In the embodiments described above, the display device of this disclosure is described by taking a liquid crystal display device as an example. However, those skilled in the art shall understand that the display device in this disclosure can also be an OLED. In particular, the blue light inhibition layer in this disclosure can be arranged above the light emitting layer of the OLED such that blue light emitted from the light emitting layer passes through the blue light inhibition layer, thereby effectively preventing blue light harm.

According to an embodiment of this disclosure, a manufacturing process of a display device comprises forming a blue light inhibition layer in the path of blue light emitted by a light source in a display substrate when manufacturing the display substrate of the display device.

For example, the step of forming a blue light inhibition layer may comprise: directly forming a blue light inhibition layer on a base plate of the display substrate.

For example, the step of forming a blue light inhibition layer may comprise: forming a blue light inhibition layer on a dielectric layer in the display substrate.

For example, after the step of forming a blue light inhibition layer, the method may comprise: etching away the blue light inhibition layer in the display area of a non-blue light subpixel region of the display substrate.

The above description of the embodiments of this disclosure is provided only for illustrative and explanatory purposes, and it is not intended to be exhaustive or to limit the content of this disclosure. Therefore, the skilled person in the art will easily conceive of many modifications and transformations. In particular, the scope of this disclosure shall be defined by the claims attached.

1. A display substrate, comprising:
a base plate; and
a blue light inhibition layer arranged on the base plate,
wherein the blue light inhibition layer weakens a portion of blue light emitted by a light source.

2. The display substrate according to claim 1, wherein
to the blue light inhibition layer is directly formed on the base plate.

3. The display substrate according to claim 1, wherein
the display substrate further comprises a thin film transistor, a passivation layer and a pixel electrode formed on the base plate; and
the thin film transistor comprises a gate, a gate insulation layer, an active region and a source/drain electrode.

4. The display substrate according to claim 3, wherein
the blue light inhibition layer is formed on the gate insulation layer; and
the pixel electrode is electrically connected to the source/drain electrode of the thin film transistor through a via hole penetrating through the passivation layer.

5. The display substrate according to claim 3, wherein
the blue light inhibition layer is formed on the passivation layer; and
the pixel electrode is electrically connected to the source/drain electrode of the thin film transistor through a via hole penetrating through the blue light inhibition layer and the passivation layer.

6. The display substrate according to claim 4, wherein
the display substrate comprises a blue subpixel region and a non-blue subpixel region, and
in a display area of the non-blue subpixel region, the display substrate comprises the base plate and the pixel electrode formed on the base plate.

7. The display substrate according to claim 6, wherein
in the display area of the non-blue subpixel region, the display substrate comprises the base plate, a planarizing layer and the pixel electrode formed on the planarizing layer.

8. The display substrate according to claim 2, wherein
the display substrate further comprises a black matrix layer and a color filter which are formed on the blue light inhibition layer.

9. The display substrate according to claim 1, wherein
the display substrate further comprises a thin film transistor and a pixel electrode which are formed on a first side of the base plate, and a black matrix layer and a color filter which are formed on the first side or a second side of the base plate; and
the blue light inhibition layer is formed on the first or second side of the base plate.

10. The display substrate according to claim 1, wherein
in the optical path of the blue light emitted by the light source, the blue light inhibition layer comprises a first transparent dielectric layer and a second transparent dielectric layer which are arranged on a transparent dielectric base layer;
a refractive index n₁ of the first transparent dielectric layer is greater than a refractive index n₀ of the transparent dielectric base layer; and
the refractive index n₁ of the first transparent dielectric layer is greater than a refractive index n₂ of the second transparent dielectric layer.

11. The display substrate according to claim 10, wherein
a thickness d of the first transparent dielectric layer is d=(2m+1)λ/(4n₁), wherein m is a natural number, n₁ is the refractive index of the first transparent dielectric layer, and λ is the wavelength of the blue light to be weakened.

12. The display substrate according to claim 10, wherein
the blue light inhibition layer comprises two or more groups of the first transparent dielectric layer and the second transparent dielectric layer stacked in sequence.

13. The display substrate according to claim 10, wherein
the refractive indexes of the first transparent dielectric layer and the second transparent dielectric layer differ by at least 0.3.

14. The display substrate according to claim 10, wherein
the transparent dielectric base layer is SiO₂, the first transparent dielectric layer is SiNₓ, and the second transparent dielectric layer is SiO₂.

15. The display substrate according to claim 14, wherein
the thickness of the first transparent dielectric layer is 58-62 nm.

16. A display device, comprising a display substrate, the display substrate comprising a base plate and a blue light inhibition layer arranged on the base plate, wherein the blue light inhibition layer weakens a portion of blue light emitted by a light source.

17. A method for manufacturing a display device, wherein during manufacturing the display substrate of the display device, the method comprises the step of:
forming in the display substrate a blue light inhibition layer in the path of blue light emitted by a light source.

18. The method according to claim 17, wherein
the step of forming a blue light inhibition layer comprises:
directly forming a blue light inhibition layer on a base plate of the display substrate.

19. The method according to claim 17, wherein
the step of forming a blue light inhibition layer comprises:
forming a blue light inhibition layer on a dielectric layer in the display substrate.

20. The method according to claim 17, wherein
after the step of forming a blue light inhibition layer, the method comprises:
etching away the blue light inhibition layer in a display area of a non-blue light subpixel region of the display substrate.
